(19) United States
(12) Patent Application Publication
(10) Pub. No.: US 2023/0391052 A1
(43) Pub. Date: Dec. 7, 2023

(54) POLYMER FILM AND LAMINATE

(71) Applicant: FUJIFILM Corporation, Tokyo (JP)

(72) Inventors: Takeaki SAWAYA, Shizuoka (JP); Akira YAMADA, Shizuoka (JP)

(73) Assignee: FUJIFILM Corporation, Tokyo (JP)

(21) Appl. No.: 18/451,802

(22) Filed: Aug. 17, 2023

Related U.S. Application Data
(63) Continuation of application No. PCT/JP2022/005629, filed on Feb. 14, 2022.

(30) Foreign Application Priority Data
Feb. 24, 2021 (JP) 2021-027772

(51) Int. Cl. B32B 15/09; C09K 19/38; C09K 19/52

(52) U.S. Cl. CPC B32B 15/09; C09K 19/3814; C09K 19/3809; C09K 19/52; B32B 2305/55; B32B 2250/03; B32B 2250/40; B32B 2307/204; B32B 2311/12; B32B 2367/00; B32B 2371/00

(57) ABSTRACT

An object of the present invention is to provide a polymer film having a more excellent adhesiveness to a metal layer. In addition, another object of the present invention is to provide a laminate having the polymer film. The polymer film of an embodiment of the present invention is a polymer film including a polymer and having a dielectric loss tangent of 0.005 or less under the conditions of a temperature of 23° C. and a frequency of 28 GHz, in which a relaxation peak disappearance temperature of a relaxation peak in a frequency dependence of the dielectric loss tangent of the polymer film is −80° C. or higher. In addition, the polymer film of the embodiment of the present invention is a polymer film including a polymer and having a dielectric loss tangent of 0.005 or less under the conditions of a temperature of 23° C. and a frequency of 28 GHz, in which an A value obtained by a predetermined measurement method is 1 to 60 eq/t.

### CROSS-REFERENCE TO RELATED APPLICATIONS

This application is a Continuation of PCT International Application No. PCT/JP2022/005629 filed on Feb. 14, 2022, which claims priority under 35 U.S.C. § 119(a) to Japanese Patent Application No. 2021-027772 filed on Feb. 24, 2021. The above applications are hereby expressly incorporated by reference, in their entirety, into the present application.

### BACKGROUND OF THE INVENTION

### 1. Field of the Invention

The present invention relates to a polymer film and a laminate.

### 2. Description of the Related Art

Higher frequency bands than ever before have been used in a 5^{th} generation (5G) mobile communication system, which is considered to be next-generation communication technology. Therefore, a substrate film for a circuit board for the 5G mobile communication system is required to have a low dielectric loss tangent and a low water absorption from the viewpoint of reducing a transmission loss in a high frequency band, and development of substrate films using various materials is in progress. One of such substrate films is a polymer film including a liquid crystal polymer. The liquid crystal polymer (LCP) film has a lower dielectric loss tangent and a lower water absorption than films commonly used in 4^{th} generation (4G) mobile communication systems, such as a polyimide film and a glass epoxy film.

For example, WO2020/218405A describes a low-dielectric resin composition including a liquid crystal polymer (A) and a graft-modified polyolefin (B) having a polar group, the low-dielectric resin composition having a relative permittivity at a frequency of 10 GHz that is a value lower than the relative permittivity of the liquid crystal polymer (A) at a frequency of 10 GHz, and a dielectric loss tangent at a frequency of 10 GHz that is a value lower than the dielectric loss tangent of the graft-modified polyolefin (B) at a frequency of 10 GHz; and a film consisting of the low-dielectric resin composition.

### SUMMARY OF THE INVENTION

As described above, a laminate having a polymer film having a low dielectric loss tangent and a metal layer has been used in the manufacture of a circuit board. In such a laminate, in a case where peeling of the metal layer occurs from the polymer film due to, for example, a change in environment such as a process for manufacturing a circuit board or a change in temperature and the like during use of the circuit board, the reliability of the circuit board is impaired. Therefore, it is required to improve the adhesiveness between the polymer film and the metal layer.

The present inventors have manufactured a polymer film with reference to the film described in WO2020/218405A, and have bonded the polymer film and a metal layer to each other to manufacture a laminate according to an aspect of using the polymer film as a circuit substrate. Thus, they have found that there is room for further improvement in the adhesiveness between the film and the metal layer.

The present invention has been made in view of the circumstances, and thus, has an object to provide a polymer film having a more excellent adhesiveness to a metal layer.

In addition, another object of the present invention is to provide a laminate having the polymer film.

The present inventors have conducted intensive studies to accomplish the object, and as a result, they have found that the object can be accomplished by the following configurations.

[1] A polymer film having a dielectric loss tangent under conditions of a temperature of 23° C. and a frequency of 28 GHz of 0.005 or less,
in which a maximum value of a temperature at which a relaxation peak is not measured on a frequency-dependent curve of the dielectric loss tangent of the polymer film, obtained by measurement in a frequency range of 1 to 10⁷ Hz, is −80° C. or higher.

[2] A polymer film having a dielectric loss tangent under conditions of a temperature of 23° C. and a frequency of 28 GHz of 0.005 or less,
in which an A value obtained by a measurement method 1 which will be described later is 1 to 60 eq/t.

[3] The polymer film according to [1] or [2],
in which the polymer film includes a compound having a structure of a liquid crystal polymer and a structure of a non-liquid crystal compound.

[4] The polymer film according to any one of [1] to [3],
in which the polymer film is formed of a composition including a liquid crystal polymer having a reactive group at a terminal and a non-liquid crystal compound having a functional group that reacts with or interacts with the reactive group.

[5] The polymer film according to [4],
in which the functional group is a group capable of forming a covalent bond by reacting with the reactive group.

[6] The polymer film according to [5],
in which the group capable of forming a covalent bond is at least one functional group selected from the group consisting of an epoxy group, an amino group, an oxetanyl group, an isocyanate group, an acid anhydride group, a carbodiimide group, an N-hydroxyester group, a glyoxal group, an imidoester group, an alkyl halide group, a thiol group, a hydroxyphenyl group, and a carboxy group.

[7] The polymer film according to [4],
in which the functional group is a group capable of forming an ion bond with the reactive group, a group capable of forming a hydrogen bond with the reactive group, or a group having a dipole-dipole interaction with the reactive group.

[8] The polymer film according to any one of [3] to [7],
in which a content of the non-liquid crystal compound in the polymer film is 0.1% to 50% by mass with respect to a total mass of the polymer film.

[9] The polymer film according to any one of [3] to [8],
in which the non-liquid crystal compound is a polymer compound.

[10] The polymer film as described in any one of [3] to [9],
in which the liquid crystal polymer has a melting point of 250° C. or higher.

[11] The polymer film as described in any one of [3] to [10],
in which the liquid crystal polymer has a melting point of 380° C. or lower.

[12] The polymer film as described in any one of [3] to [11],
in which the liquid crystal polymer has at least one selected from the group consisting of repeating units represented by Formulae (1) to (3) which will be described later.

[13] The film as described in any one of [3] to [12],
in which the liquid crystal polymer has at least one selected from the group consisting of a repeating unit derived from parahydroxybenzoic acid and a repeating unit derived from 6-hydroxy-2-naphthoic acid.

[14] The liquid crystal polymer film as described in any one of [3] to [13],
in which the liquid crystal polymer has at least one selected from the group consisting of a repeating unit derived from 6-hydroxy-2-naphthoic acid, a repeating unit derived from an aromatic diol compound, a repeating unit derived from terephthalic acid, and a repeating unit derived from 2,6-naphthalenedicarboxylic acid.

[15] A laminate comprising:
the polymer film as described in any one of [1] to [14]; and
a metal layer arranged on at least one surface of the polymer film.

[16] The laminate according to [15],
in which two of the metal layers are arranged on both surfaces of the polymer film.

[17] The laminate according to [15] or [16],
in which the metal layer is a copper layer.

[18] The laminate according to any one of [15] to [17],
in which a maximum height Rz of a surface of the metal layer on a side facing the polymer film is 5 m or less.

[19] The laminate according to any one of [15] to [18],
in which a peel strength between the polymer film and the metal layer is more than 0.5 kN/m.

According to the present invention, it is possible to provide a polymer film having an excellent adhesiveness to a metal layer. In addition, according to the present invention, it is possible to provide a laminate having the polymer film.

### BRIEF DESCRIPTION OF THE DRAWINGS

FIG. 1 is a graph showing the frequency dependence of the dielectric loss tangent of a polymer film.

### DESCRIPTION OF THE PREFERRED EMBODIMENTS

Hereinafter, the present invention will be described in detail.

Description of configuration requirements described below may be made on the basis of representative embodiments of the present invention in some cases, but the present invention is not limited to such embodiments.

In notations for a group (atomic group) in the present specification, in a case where the group is noted without specifying whether it is substituted or unsubstituted, the group includes both a group having no substituent and a group having a substituent as long as this does not impair the spirit of the present invention. For example, an “alkyl group” includes not only an alkyl group having no substituent (unsubstituted alkyl group), but also an alkyl group having a substituent (substituted alkyl group). In addition, an “organic group” in the present specification refers to a group including at least one carbon atom.

In the present specification, in a case where the polymer film is in the form of a long film, a width direction of the polymer film means the lateral direction and the transverse direction (TD), and a length direction means the longitudinal direction and the machine direction (MD) of the polymer film.

In the present specification, for each component, one kind of substance corresponding to each component may be used alone, or two or more kinds thereof may be used in combination. Here, in a case where two or more kinds of substances are used for each component, the content of the component indicates a total content of two or more substances unless otherwise specified.

In the present specification, “to” is used in a meaning including numerical values denoted before and after “to” as a lower limit value and an upper limit value, respectively. In the present specification, the dielectric loss tangent of the polymer film or the polymer as measured under the conditions of a temperature of 23° C. and a frequency of 28 GHz is also described as a “standard dielectric loss tangent”.

In the present specification, the “film width” means a distance between both ends of a long polymer film in the width direction.

In the present specification, the polymer film may be simply referred to as a “film”.

[Polymer Film]

### First Embodiment

A first embodiment of the present invention will be described.

The polymer film according to the first embodiment of the present invention is a polymer film having a standard dielectric loss tangent of 0.005 or less, in which a maximum value (hereinafter also referred to as a “relaxation peak disappearance temperature”) of a temperature at which a relaxation peak is not measured on a frequency-dependent curve of the dielectric loss tangent of the polymer film, obtained by measurement in a frequency range of 1 to 10⁷ Hz, is −80° C. or higher.

<Dielectric Characteristics>

The standard dielectric loss tangent of the polymer film according to the present embodiment is 0.005 or less. The standard dielectric loss tangent of the polymer film according to the present embodiment is preferably 0.003 or less, more preferably 0.002 or less, and still more preferably 0.001 or less. The lower limit value is not particularly limited, and may be 0.0001 or more.

A relative permittivity of the polymer film according to the present embodiment varies depending on the application, but is preferably 2.0 to 4.0, and more preferably 2.5 to 3.5. The dielectric characteristics including a standard dielectric loss tangent of the polymer film can be measured by a cavity resonator perturbation method. A specific method for measuring the dielectric characteristics of the polymer film will be described in the section of Examples which will be described later.

<Relaxation Peak Disappearance Temperature>

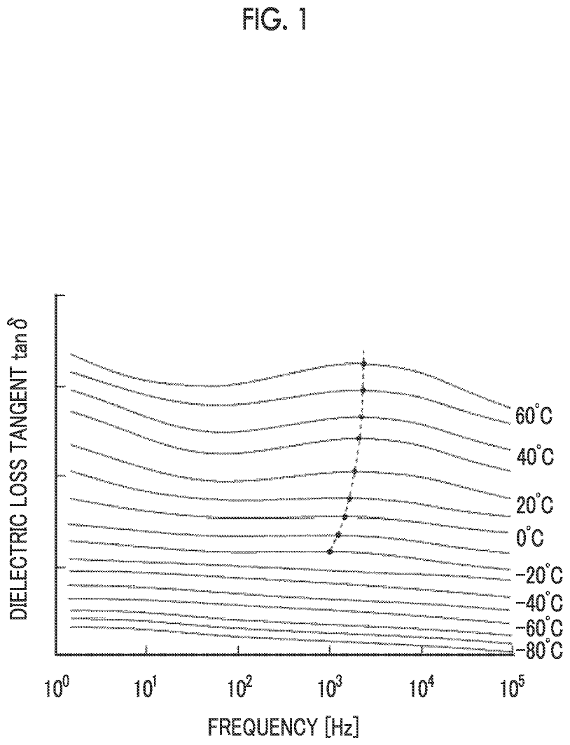

The relaxation peak disappearance temperature of the polymer film will be described with reference to FIG. 1.

FIG. 1 is a graph showing the frequency dependence of the dielectric loss tangent of a polymer film, in which one curve shows a value of the dielectric loss tangent at each frequency in a case where the dielectric loss tangent is measured by setting the temperature to a predetermined value and changing the frequency. As shown in FIG. 1, the dielectric loss tangent of the polymer film shows a frequency dependence in which the dielectric loss tangent fluctuates depending on the frequency, and a peak (relaxation peak) is shown on the curve in a frequency range of 1 to 10⁷ Hz at a measurement temperature on the higher temperature side. Here, the peak refers to a point where a value obtained by differentiating the dielectric loss tangent with respect to the frequency is 0. The vertex of the relaxation peak tends to shift to the low frequency side as the measurement temperature decreases (see the broken line in FIG. 1). Eventually, the relaxation peak is not measured from the curve at a certain measurement temperature or lower, and in the curve, the dielectric loss tangent decreases monotonically as the frequency increases.

The present inventors have conducted intensive studies on the peeling of a metal layer from a laminate having a polymer film and the metal layer, and a cause of the peeling. As a result, they have found that a polymer film having a configuration in which the polymer film has a standard dielectric loss tangent of 0.005 or less and the relaxation peak disappearance temperature is −80° C. or higher exerts an effect that the adhesiveness to a metal layer is more excellent (hereinafter also referred to as “the effect of the present invention”). A reason why the polymer film according to the present embodiment exerts the effect of the present invention is not clear, but is presumed to be as follows by the present inventors.

Examples of a cause of the peeling of the metal layer from the laminate with the polymer film and the metal layer include cohesive failure that occurs inside the polymer film, and interfacial peeling occurring at an interface between the polymer film and the metal layer. Here, the relaxation peak disappearance temperature based on a frequency dependence of the dielectric loss tangent of the polymer film is considered to be an index indicating an ease of movement of a terminal of a polymer molecule (for example, a liquid crystal polymer) in the film. In a case where the relaxation peak disappearance temperature is equal to or higher than a predetermined value, it is presumed that a terminal group of a polymer molecule is constrained by the presence of, for example, a component (for example, a non-liquid crystal compound which will be described later) that reacts with or interacts with the terminal group of a polymer molecule in the film, and the movement is restricted. Then, even in a case where the dimensions of the polymer molecules are changed due to a change in ambient temperature, it is considered that the polymer molecules are difficult to separate from each other due to factors such as an intermolecular interaction. As a result, it is presumed that the cracks or fissures that cause the cohesive failure are less likely to occur, and the adhesiveness between the polymer film and the metal layers (peeling resistance) is improved.

The relaxation peak disappearance temperature of the polymer film is measured by the following method.

First, using a sample cut out from the polymer film, the dielectric loss tangent of the polymer film in a frequency range of 1 to 10⁷ Hz is measured by a cavity resonator perturbation method, and the frequency dependence of the dielectric loss tangent is measured. The measurement of the frequency dependence of the dielectric loss tangent is performed in a range of −90° C. to 60° C. while changing the temperature condition every 10° C. Next, a curve showing the frequency dependence of the dielectric loss tangent of the polymer film under each temperature condition is created, and the appearance of a relaxation peak on the curve is confirmed. Confirmation of the appearance of a relaxation peak is performed by confirming the existence of a region in which the dielectric loss tangent increases as the frequency increases in each curve. That is, frequencies F1 and F₂ included in the range of 1 to 10⁷ Hz, in which DF₁ and DF₂, measured values of the dielectric loss tangent in each of the frequencies, satisfy F₁<F₂ and DF₁<DF₂, exist, it is determined that a relaxation peak has appeared, and in a case where the frequencies F₁ and F₂ do not exist, it is determined that a relaxation peak has not appeared.

Among the curves in which a relaxation peak is determined not to appear by the method, the temperature of a curve having the highest temperature condition is a measured relaxation peak disappearance temperature of the polymer film.

The measurement of the frequency dependence of the dielectric loss tangent of the polymer film can be carried out by using a dielectric loss tangent measuring device (for example, “Alpha-A Analyzer” manufactured by Novocontrol Technologies GmbH & Co. KG).

The relaxation peak disappearance temperature of the polymer film is preferably −75° C. or higher, more preferably −70° C. or higher, still more preferably −50° C. or higher, and particularly preferably −30° C. or higher from the viewpoint that the effect of the present invention is more excellent. The upper limit value is not particularly limited and may be 0° C. or lower.

Examples of a method for adjusting the relaxation peak disappearance temperature include a method in which a component having a functional group capable of being bonded to a terminal group of a polymer molecule constituting the polymer film is added to a raw material composition for the polymer film, and a method in which in a process for producing the polymer film, a heat treatment such as a post-heating treatment which will be described later is performed, thereby accelerating an interaction between a polymer molecule constituting the polymer film and other components to limit a terminal group of the polymer molecule.

### Second Embodiment

A second embodiment of the present invention will be described.

The polymer film according to the second embodiment of the present invention is a polymer film having a standard dielectric loss tangent of 0.005 or less, in which an A value obtained by the measurement method 1 which will be described later is 1 to 60 eq/t.

<Dielectric Characteristics>

The dielectric characteristics of the polymer film according to the present embodiment, including preferred ranges thereof, are as described with respect to the polymer film according to the first embodiment.

<A value>

The A value of the polymer film can be obtained by the following measurement method 1.

Measurement method 1: An A value (unit: eq/t) is calculated according to the following Expression (A1) from a number-average molecular weight in terms of standard polystyrene obtained by gel permeation chromatography (GPC) for a polymer solution obtained by dissolving a polymer film in a solvent.

A value=(10⁶/number-average molecular weight)×2 Expression (A1)

The measurement of GPC can be carried out with the following device and conditions.

“HLC (registered trademark)-8320GPC” manufactured by Tosoh Corporation is used as a measuring device, and two TSKgel (registered trademark) SuperHM-H (6.0 mm ID×15 cm, manufactured by Tosoh Corporation) are used as a column. A solvent (eluent) for dissolving the polymer film is not particularly limited, and examples thereof include a mixed solution of pentafluorophenol/chloroform=1/2 (mass ratio). The measurement conditions are as follows: a sample concentration of 0.03% by mass, a flow rate of 0.6 ml/min, a sample injection amount of 20 μL, and a measurement temperature of 40° C. Detection is performed using an RI (differential refractometry) detector.

The calibration curve was created using 8 samples of “F-40”, “F-20”, “F-4”, “F-1”, “A-5000”, “A-2500”, “A-1000”, and “n-propylbenzene” which are “Standard Samples TSK standard, polystyrene” (manufactured by TOSOH Corporation).

The present inventors have found that a polymer film having a configuration in which the polymer film has a standard dielectric loss tangent of 0.005 or less and an A value is 1 to 60 eq/t exerts the effects of the present invention. A reason why the polymer film according to the present embodiment exerts the effect of the present invention is not clear, but is presumed to be as follows by the present inventors.

As described in the description of the first embodiment, it is presumed that in a case where there occurs a reaction or interaction between a terminal group of the polymer molecule included in the film and a functional group of the component existing around the polymer molecule, a movement of the terminal of the polymer molecule is limited, and even in a case where the dimensions of the polymer molecules are changed due to a change in temperature, the polymer molecules are difficult to separate from each other. As a result, a cohesive failure occurring inside the film is suppressed and the adhesiveness between the polymer film and the metal layer is improved. Here, the A value of the polymer film measured by the method is considered to be an index indicating a concentration of a terminal group that does not react with or interact with the surrounding components in the film. That is, a reaction or interaction (associate) appropriately occurs between a terminal group of the polymer molecule and a functional group of the surrounding component in the inside of the film in which the A value is in the range, and as a result, the cohesive failure is suppressed as described above, and the adhesiveness between the polymer film and the metal layer is improved.

As described above, the A value is 60 eq/t or less, and from the viewpoint that the effect of the present invention is more excellent, the A value is preferably 50 eq/t or less, more preferably 40 eq/t or less, still more preferably 25 eq/t or less, particularly preferably 18 eq/t or less, and most preferably 15 eq/t or less.

In addition, the A value is 1 eq/t or more. In a case where the A value of the polymer film is 1 eq/t or more, the fluidity during molding can be secured and the molding is easier.

Furthermore, the unit “eq/t” of the A value means a molar equivalent of a terminal group which is estimated to be unconstrained per weight (ton) of the polymer film.

Examples of a method for adjusting the A value include the methods described as the method for adjusting the relaxation peak disappearance temperature.

Hereinafter, the polymer film according to the first embodiment and the polymer film according to the second embodiment will be described in more detail.

In the present specification, “the film of the embodiment of the present invention” or “the present film” is intended to be a generic term for both the polymer film according to the first embodiment and the polymer film according to the second embodiment.

[Configuration of Film]

The configuration of the present film is not particularly limited as long as the standard dielectric loss tangent is 0.005 or less and a polymer film satisfying at least one of the requirement of the peak disappearance temperature or the requirement of the A value requirement can be formed.

The present film preferably has a structure of a polymer having a low standard dielectric loss tangent (preferably 0.005 or less) and a structure of a non-liquid crystal compound (which will be described later) having a functional group capable of reacting or interacting with the polymer.

The polymer having a low standard dielectric loss tangent is not particularly limited as long as the standard dielectric loss tangent is 0.005 or less, and examples thereof include a liquid crystal polymer, a polyimide, a modified polyimide, and a fluororesin.

Hereinafter, the present film will be described in more detail by taking a liquid crystal polymer as an example.

<Liquid Crystal Polymer>

The present film preferably has a structure of the liquid crystal polymer.

As the liquid crystal polymer, a thermotropic liquid crystal polymer is preferable. The thermotropic liquid crystal polymer means a polymer which exhibits liquid crystallinity in a molten state in case of heating it in a predetermined temperature range.

The thermotropic liquid crystal polymer is not particularly limited in terms of the chemical composition as long as it is a melt-moldable liquid crystal polymer, and examples thereof include a thermoplastic liquid crystal polyester and a thermoplastic polyester amide with an amide bond introduced into the thermoplastic liquid crystal polyester.

As the liquid crystal polymer, for example, the thermoplastic liquid crystal polymer described in WO2015/064437A and JP2019-116586A can be used.

Specific preferred examples of the liquid crystal polymer include a thermoplastic liquid crystal polyester or thermoplastic liquid crystal polyester amide having a repeating unit derived from at least one selected from the group consisting of an aromatic hydroxycarboxylic acid, an aromatic or aliphatic diol, an aromatic or aliphatic dicarboxylic acid, an aromatic diamine, an aromatic hydroxyamine, and an aromatic aminocarboxylic acid.

Examples of the reactive group contained at a terminal of the liquid crystal polymer include a carboxy group, a hydroxyl group, and an amino group, and the carboxy group or the phenolic hydroxyl group is preferable, and the carboxy group is more preferable.

The number of the reactive groups contained at a terminal of the liquid crystal polymer is preferably 1 or 2, and more preferably 2.

Examples of the aromatic hydroxycarboxylic acid include parahydroxybenzoic acid, metahydroxybenzoic acid, 6-hydroxy-2-naphthoic acid, and 4-(4-hydroxyphenyl)benzoic acid. These compounds may have substituents such as a halogen atom, a lower alkyl group, and a phenyl group. Among these, the parahydroxybenzoic acid or the 6-hydroxy-2-naphthoic acid is preferable.

As the aromatic or aliphatic diol, the aromatic diol is preferable. Examples of the aromatic diol include hydroquinone, 4,4′-dihydroxybiphenyl, 3,3′-dimethyl-1,1′-biphenyl-4,4′-diol, and acylated products thereof, and hydroquinone or 4,4′-dihydroxybiphenyl is preferable.

As the aromatic or aliphatic dicarboxylic acid, the aromatic dicarboxylic acid is preferable. Examples of the aromatic dicarboxylic acid include terephthalic acid, isophthalic acid, and 2,6-naphthalenedicarboxylic acid, and terephthalic acid is preferable.

Examples of the aromatic diamine, the aromatic hydroxyamine, and the aromatic aminocarboxylic acid include p-phenylenediamine, 4-aminophenol, and 4-aminobenzoic acid.

In addition, it is preferable that the liquid crystal polymer has at least one selected from the group consisting of the repeating units represented by Formulae (1) to (3).

—O—Ar1-CO— (1)

—CO—Ar2-CO— (2)

—X—Ar3-Y— (3)

In Formula (1), Ar1 represents a phenylene group, a naphthylene group, or a biphenylylene group.

In Formula (2), Ar2 represents a phenylene group, a naphthylene group, a biphenylylene group, or a group represented by Formula (4).

In Formula (3), Ar3 represents a phenylene group, a naphthylene group, a biphenylylene group, or the group represented by Formula (4), and X and Y each independently represent an oxygen atom or an imino group.

—Ar4-Z—Ar5- (4)

In Formula (4), Ar4 and Ar5 each independently represent a phenylene group or a naphthylene group, and Z represents an oxygen atom, a sulfur atom, a carbonyl group, a sulfonyl group, or an alkylene group.

The phenylene group, the naphthylene group, and the biphenylylene group may have a substituent selected from the group consisting of a halogen atom, an alkyl group, and an aryl group.

Among those, the liquid crystal polymer preferably has at least one selected from the group consisting of the repeating unit derived from an aromatic hydroxycarboxylic acid represented by Formula (1), the repeating unit derived from an aromatic diol represented by Formula (3), in which both X and Y are oxygen atoms, and the repeating unit derived from an aromatic dicarboxylic acid represented by Formula (2).

Among those, the liquid crystal polymer more preferably has at least the repeating unit derived from an aromatic hydroxycarboxylic acid, still more preferably has at least one selected from the group consisting of a repeating unit derived from parahydroxybenzoic acid and a repeating unit derived from 6-hydroxy-2-naphthoic acid, and particularly preferably has the repeating unit derived from parahydroxybenzoic acid and the repeating unit derived from 6-hydroxy-2-naphthoic acid.

In addition, in another preferred aspect, the liquid crystal polymer preferably has at least one selected from the group consisting of the repeating unit derived from 6-hydroxy-2-naphthoic acid, the repeating unit derived from an aromatic diol, a repeating unit derived from terephthalic acid, and a repeating unit derived from a 2,6-naphthalenedicarboxylic acid, and more preferably has all of the repeating unit derived from 6-hydroxy-2-naphthoic acid, the repeating unit derived from an aromatic diol, the repeating unit derived from terephthalic acid, and the repeating unit derived from 2,6-naphthalenedicarboxylic acid.

In a case where the liquid crystal polymer includes the repeating unit derived from an aromatic hydroxycarboxylic acid, a compositional ratio of the repeating unit is preferably 50% to 65% by mole with respect to all the repeating units of the liquid crystal polymer. In addition, it is also preferable that the liquid crystal polymer has only the repeating unit derived from an aromatic hydroxycarboxylic acid.

In a case where the liquid crystal polymer includes the repeating unit derived from an aromatic diol, a compositional ratio of the repeating unit is preferably 17.5% to 25% by mole with respect to all the repeating units of the liquid crystal polymer.

In a case where the liquid crystal polymer includes the repeating unit derived from an aromatic dicarboxylic acid, a compositional ratio of the repeating unit is preferably 11% to 23% by mole with respect to all the repeating units of the liquid crystal polymer.

In a case where the liquid crystal polymer includes the repeating unit derived from any of an aromatic diamine, an aromatic hydroxyamine, and an aromatic aminocarboxylic acid, a compositional ratio of the repeating unit is preferably 2% to 8% by mole with respect to all the repeating units of the liquid crystal polymer.

A method for synthesizing the liquid crystal polymer is not particularly limited, and the compound can be synthesized by polymerizing the compound by a known method such as melt polymerization, solid phase polymerization, solution polymerization, and slurry polymerization.

As the liquid crystal polymer, a commercially available product may be used. Examples of the commercially available product of the liquid crystal polymer include “LAPEROS” manufactured by Polyplastics Co., Ltd., “VECTRA” manufactured by Celanese Corporation, “UENO LCP” manufactured by Ueno Fine Chemicals Industry, Ltd., “SUMIKA SUPER LCP” manufactured by Sumitomo Chemical Co., Ltd., “XYDAR” manufactured by ENEOS LC Co., Ltd., and “SIVERAS” manufactured by Toray Industries, Inc.

The standard dielectric loss tangent of the liquid crystal polymer is preferably 0.005 or less, more preferably 0.003 or less, and still more preferably 0.002 or less from the viewpoint that a film having a standard dielectric loss tangent of 0.005 or less can be produced and a communication circuit board with a smaller transmission loss can be manufactured.

The lower limit value is not particularly limited, and may be, for example, 0.0001 or more.

In a case where the film includes two or more kinds of liquid crystal polymers, the “dielectric loss tangent of the liquid crystal polymer” means a mass-average value of the dielectric loss tangents of two or more kinds of liquid crystal polymers.

The standard dielectric loss tangent of the liquid crystal polymer included in the film can be measured by the following method.

First, after performing immersion in an organic solvent (for example, pentafluorophenol) in an amount of 1,000 times by mass with respect to the total mass of the film, the mixture is heated at 120° C. for 12 hours to elute the organic solvent-soluble components including the liquid crystal polymer into the organic solvent. Next, the eluate including the liquid crystal polymer and the non-eluted components are separated by filtration. Subsequently, acetone is added to the eluate as a poor solvent to precipitate a liquid crystal polymer, and the precipitate is separated by filtration.

A standard dielectric loss tangent of the liquid crystal polymer can be obtained by filling a polytetrafluoroethylene (PTFE) tube (outer diameter: 2.5 mm, inner diameter: 1.5 mm, length: 10 mm) with the obtained precipitate, measuring the dielectric characteristics by a cavity resonator perturbation method under the conditions of a temperature of 23° C. and a frequency of 28 GHz, using a cavity resonator (for example, “CP-531” manufactured by Kanto Electronics Application & Development, Inc.), and correcting the influence of voids in the PTFE tube by a Bruggeman formula and a void ratio.

The void ratio (volume fraction of the void in the tube) is calculated as follows. The volume of a space inside the tube is determined from the inner diameter and the length of the tube. Next, the weights of the tube before and after filling the precipitate are measured to determine the mass of the filled precipitate, and then the volume of the filled precipitate is determined from the obtained mass and the specific gravity of the precipitate. The void ratio can be calculated by dividing the volume of the precipitate thus obtained by the volume of the space in the tube determined above to calculate a filling rate.

Furthermore, in a case where a commercially available product of the liquid crystal polymer is used, a numerical value of the dielectric loss tangent described as a catalog value of the commercially available product may be used.

As for the liquid crystal polymer, the melting point Tm is preferably 250° C. or higher, more preferably 280° C. or higher, and still more preferably 310° C. or higher from the viewpoint that the heat resistance is more excellent.

The upper limit value of the melting point Tm of the liquid crystal polymer is not particularly limited, but is preferably 400° C. or lower, and more preferably 380° C. or lower from the viewpoint that the moldability is more excellent.

The melting point Tm of the liquid crystal polymer can be determined by measuring a temperature at which the endothermic peak appears, using a differential scanning calorimeter (“DSC-60A” manufactured by Shimadzu Corporation). In a case where a commercially available product of the liquid crystal polymer is used, the melting point Tm described as the catalog value of the commercially available product may be used.

A number-average molecular weight (Mn) of the liquid crystal polymer is not particularly limited, but is preferably 10,000 to 600,000, and more preferably 30,000 to 150,000.

The number-average molecular weight of the liquid crystal polymer is a polystyrene-equivalent value measured by GPC, and can be measured by a method similar to the method for measuring the number-average molecular weight of the polymer film.

The liquid crystal polymers may be used alone or in combination of two or more kinds thereof.

The content of the liquid crystal polymer is preferably 10% to 100% by mass, more preferably 30% to 95% by mass, and still more preferably 50% to 90% by mass with respect to the total mass of the film.

Furthermore, the content of the liquid crystal polymer and the components which will be described later in the polymer film can be measured by a known method such as infrared spectroscopy and gas chromatography mass spectrometry.

<Non-Liquid Crystal Compound>

The present film preferably includes a structure of a non-liquid crystal compound (hereinafter also simply referred to as a “non-liquid crystal compound”) having a functional group capable of reacting with or interacting with a liquid crystal polymer together with the structure of the liquid crystal polymer. A polymer film is manufactured using the liquid crystal polymer and the non-liquid crystal compound, and by causing a reaction or interaction with a reactive group at a terminal of the liquid crystal polymer, the motility of the liquid crystal polymer can be controlled and the adhesiveness to the metal layer can be improved.

The non-liquid crystal compound is not particularly limited as long as it is a compound having a functional group capable of reacting with or interacting with a liquid crystal polymer.

Examples of the functional group contained in the non-liquid crystal compound include a group (hereinafter also referred to as a “covalent-bonding group”) capable of forming a covalent bond by reacting with the reactive group contained at a terminal of a liquid crystal polymer. In addition, examples of the functional group contained in the non-liquid crystal compound include a group (hereinafter also referred to as an “ion-bonding group”) capable of forming a bond with the reactive group, a group (hereinafter referred to as a “hydrogen-bonding group”) capable of forming a hydrogen bond with the reactive group, and a group (hereinafter also referred to as a “dipole-dipole interaction group”) capable of having a dipole-dipole interaction with the reactive group.

Among those, the covalent-bonding group or the ion-bonding group is preferable, and the covalent-bonding group is more preferable from the viewpoint that the effect of the present invention is more excellent.

Examples of the covalent-bonding group include an epoxy group, an amino group, an oxetanyl group, an isocyanate group, an acid anhydride group, a carbodiimide group, an N-hydroxyester group, a glyoxal group, an imidoester group, an alkyl halide group, a thiol group, a hydroxyphenyl group, and a carboxy group, among the epoxy group, the amino group, the isocyanate group, the acid anhydride group, or the carbodiimide group is preferable, and the epoxy group or the amino group is more preferable.

Examples of the ion-bonding group include a carboxylate anionic group (—COO⁻), a sulfonate anionic group (—SO₃⁻), a phosphoric ester anionic group, a quaternary ammonium group (—NH₄⁺), a quaternary phosphonium group (—PH₄⁺), and a salt thereof with a counter ion, and the carboxylate anion group is preferable.

Examples of the hydrogen-bonding group include a hydroxyl group, a carbonyl group, and an amino group.

Examples of the dipole-dipole interaction group described above include a hydroxyl group, a carbonyl group, and an amino group.

The non-liquid crystal compound may be a low-molecular-weight compound or a high-molecular-weight compound, but is preferably the high-molecular-weight compound.

In the present specification, a compound having a molecular weight of 1,000 or less is referred to as a “low-molecular-weight compound”, and a compound having a molecular weight (number-average molecular weight) of more than 1,000 is referred to as a “high-molecular-weight compound”.

Examples of the non-liquid crystal low-molecular-weight compound having a covalent-bonding group as a functional group include a bisphenol A type epoxy compound, a bisphenol F type epoxy compound, a phenol novolac type epoxy compound, a cresol novolac type epoxy compound, and a diisocyanate compound.

Examples of the non-liquid crystal polymer compound having a covalent-bonding group as a functional group include an epoxy group-containing polyolefin-based copolymer, an epoxy group-containing vinyl-based copolymer, a maleic acid anhydride-containing polyolefin-based copolymer, a maleic acid anhydride-containing vinyl copolymer, an oxazoline group-containing polyolefin-based copolymer, an oxazoline group-containing vinyl-based copolymer, a carboxy group-containing olefin-based copolymer, a polyester, and a liquid crystal polyester.

Among these, the epoxy group-containing polyolefin-based copolymer or the maleic acid anhydride-grafted polyolefin-based copolymer is preferable.

Examples of the epoxy group-containing polyolefin-based copolymer include an ethylene/glycidyl methacrylate copolymer, an ethylene/glycidyl methacrylate/vinyl acetate copolymer, an ethylene/glycidyl methacrylate/methyl acrylate copolymer, a polystyrene graft copolymer to an ethylene/glycidyl methacrylate copolymer (EGMA-g-PS), a polymethylmethacrylate graft copolymer to an ethylene/glycidyl methacrylate copolymer (EGMA-g-PMMA), and an acrylonitrile/styrene graft copolymer to an ethylene/glycidyl methacrylate copolymer (EGMA-g-AS).

Examples of a commercially available product of the epoxy group-containing polyolefin-based copolymer include BONDFIRST 2C and BONDFIRST E manufactured by Sumitomo Chemical Co., Ltd.; Lotadar manufactured by Arkema S. A.; and MODIPER A4100 and MODIPER A4400 manufactured by NOF Corporation.

Examples of the epoxy group-containing vinyl-based copolymer include a glycidyl methacrylate grafted polystyrene (PS-g-GMA), a glycidyl methacrylate grafted polymethyl methacrylate (PMMA-g-GMA), and a glycidyl methacrylate grafted polyacrylonitrile (PAN-g-GMA).

Examples of the maleic acid anhydride-containing polyolefin-based copolymer include a maleic acid anhydride grafted polypropylene (PP-g-MAH), a maleic acid anhydride grafted ethylene/propylene rubber (EPR-g-MAH), and a maleic acid anhydride grafted ethylene/propylene/diene rubber (EPDM-g-MAH).

Examples of a commercially available product of the maleic acid anhydride-containing polyolefin-based copolymer include Orevac G series manufactured by Arkema S. A.; and FUSABOND E series manufactured by The Dow Chemical Company.

Examples of the maleic acid anhydride-containing vinyl copolymer include a maleic acid anhydride grafted polystyrene (PS-g-MAH), a maleic acid anhydride grafted styrene/butadiene/styrene copolymer (SBS-g-MAH), a maleic acid anhydride grafted styrene/ethylene/butene/styrene copolymer (SEBS-g-MAH and a styrene/maleic acid anhydride copolymer, and an acrylic acid ester/maleic acid anhydride copolymer.

Examples of a commercially available product of the maleic acid anhydride-containing vinyl copolymer include TUFTEC M Series (SEBS-g-MAH) manufactured by Asahi Kasei Corporation.

In addition to those, examples of the non-liquid crystal polymer compound having a covalent-bonding group as a functional group include oxazoline-based compatibilizers (for example, a bisoxazoline-styrene-maleic acid anhydride copolymer, a bisoxazoline-maleic acid anhydride-modified polyethylene, and a bisoxazoline-maleic acid anhydride-modified polypropylene), elastomer-based compatibilizers (for example, an aromatic resin and a petroleum resin), ethylene glycidyl methacrylate copolymer, an ethylene maleic acid anhydride ethyl acrylate copolymer, ethylene glycidyl methacrylate-acrylonitrile styrene, acid-modified polyethylene wax, a COOH-modified polyethylene graft polymer, a COOH-modified polypropylene graft polymer, a polyethylene-polyamide graft copolymer, a polypropylene-polyamide graft copolymer, a methyl methacrylate-butadiene-styrene copolymer, acrylonitrile-butadiene rubber, an EVA-PVC-graft copolymer, a vinyl acetate-ethylene copolymer, an ethylene-α-olefin copolymer, a propylene-α-olefin copolymer, a hydrogenated styrene-isopropylene-block copolymer, and an amine-modified styrene-ethylene-butene-styrene copolymer.

Examples of the non-liquid crystal compound having an ion-bonding group as a functional group include an ionomer resin.

Examples of such an ionomer resin include an ethylene-methacrylic acid copolymer ionomer, an ethylene-acrylic acid copolymer ionomer, a propylene-methacrylic acid copolymer ionomer, a butylene-acrylic acid copolymer ionomer, a propylene-acrylic acid copolymer ionomer, an ethylene-vinyl sulfonic acid copolymer ionomer, a styrene-methacrylic acid copolymer ionomer, a sulfonated polystyrene ionomer, a fluorine-based ionomer, a telechelic polybutadiene acrylic acid ionomer, a sulfonated ethylene-propylene-diene copolymer ionomer, hydrogenated polypentamer ionomer, a polypentamer ionomer, a poly(vinylpyridium salt) ionomer, a poly(vinyltrimethylammonium salt) ionomer, a poly(vinyl benzyl phosphonium salt) ionomer, a styrene-butadiene acrylic acid copolymer ionomer, a polyurethane ionomer, a sulfonated styrene-2-acrylamide-2-methyl propane sulfate ionomer, an acid-amine Ionomer, an aliphatic ionene, and an aromatic ionene.

Examples of the non-liquid crystal compound having a hydrogen-bonding group as a functional group include a polyester, a modified polyester, an amine-modified polyethylene, an amine-modified epoxy resin, and an amine-modified styrene-ethylene-butene-styrene copolymer.

Examples of the non-liquid crystal compound having a dipole-dipole interaction group as a functional group include a polyester, a modified polyester, an amine-modified polyethylene, an amine-modified epoxy resin, and an amine-modified styrene-ethylene-butene-styrene copolymer.

The non-liquid crystal compounds may be used alone or in combination of two or more kinds thereof.

The content of the non-liquid crystal compound is preferably 0.1% to 90% by mass, more preferably 5% to 70% by mass, and still more preferably 10% to 50% by mass with respect to the total mass of the film.

The content of the non-liquid crystal compound is preferably 0.1% to 1,000% by mass, more preferably 5% to 500% by mass, and still more preferably 10% to 100% by mass with respect to the total mass of the liquid crystal polymer.

In addition, in the non-liquid crystal compound, the content of the functional groups (hereinafter also referred to as a “functional group concentration”) with respect to the total mass of the film is preferably 0.1% by mass or more, more preferably 0.2% by mass or more, and still more preferably 0.3% by mass or more from the viewpoint that the effect of the present invention is more excellent. An upper limit thereof is not particularly limited, but is preferably 50% by mass or less, more preferably 10% by mass or less, and still more preferably 2% by mass or less.

<Composite Body>

In the present film, it is preferable that a composite body having a structure of a liquid crystal polymer and a structure of a non-liquid crystal compound is formed by an action of the non-liquid crystal compound on a terminal group of the liquid crystal polymer.

Examples of the composite body include a compound having a structure of a liquid crystal polymer and a non-liquid crystal compound, and more specifically include a copolymer formed using a liquid crystal polymer having a reactive group at a terminal and a non-liquid crystal compound having a covalent-bonding group that reacts with the reactive group as a functional group.

In addition, other examples of the composite body include an associate having a structure of a liquid crystal polymer and a structure of a non-liquid crystal compound, and more specifically include a structure formed using a liquid crystal polymer having a reactive group at a terminal and a non-liquid crystal compound having a group having an ion-bonding property with respect to the reactive group, a group having a hydrogen-bonding property with respect to the reactive group, or a group having a dipole-dipole interacting property with respect to the reactive group as a functional group, in which both the compounds are associated with each other by an ion bond, a hydrogen bond, or a dipole-dipole interaction, and thus, the liquid crystal polymer is quasi-crosslinked with the non-liquid crystal compound.

Preferred examples of the copolymer and the associate include a copolymer or associate formed from a preferred embodiment of a liquid crystal polymer and a preferred embodiment of a non-liquid crystal compound.

The polymer film preferably includes a compound having structures of a liquid crystal polymer and a non-liquid crystal compound.

The film may include only one kind or a combination of two or more kinds of composite bodies selected from the group consisting of the compound and the associate.

The content of the composite body is preferably 1% to 100% by mass, more preferably 10% to 100% by mass, and still more preferably 20% to 100% by mass with respect to the total mass of the film.

Furthermore, in a case where the polymer film includes the compound (copolymer), the content of the liquid crystal polymer is read as a content of the structure of the liquid crystal polymer, and the content of the non-liquid crystal compound is read as a content of the structure of the non-liquid crystal compound.

<Heat Stabilizer>

The present film may include a heat stabilizer for the purpose of suppressing thermal oxidative deterioration during film production through melt extrusion, and improving the leveling and the smoothness of a surface of the film.

Examples of the heat stabilizer include a phenol-based stabilizer and an amine-based stabilizer, each having a radical scavenging action; a phosphite-based stabilizer and a sulfur-based stabilizer, each having a decomposition action of a peroxide; and a hybrid stabilizer having a radical scavenging action and a decomposition action of a peroxide.

The present film preferably contains a heat stabilizer.

Examples of the phenol-based stabilizer include a hindered phenol-based stabilizer, a semi-hindered phenol-based stabilizer, and a less hindered phenol-based stabilizer.

Examples of a commercially available product of the hindered phenol-based stabilizer include ADK STAB AO-20, AO-50, AO-60, and AO-330 manufactured by ADEKA Corporation; and Irganox 259, 1035, and 1098 manufactured by BASF.

Examples of a commercially available product of the semi-hindered phenol-based stabilizer include ADK STAB AO-80 manufactured by ADEKA Corporation; and Irganox 245 manufactured by BASF.

Examples of a commercially available product of the less hindered phenol-based stabilizer include NOCRAC 300 manufactured by Ouchi Shinko Chemical Industrial Co., Ltd.; and ADK STAB AO-30 and AO-40 manufactured by ADEKA Corporation.

Examples of a commercially available product of the phosphite-based stabilizer include ADK STAB-2112, PEP-8, PEP-36, and HP-10 manufactured by ADEKA Corporation.

Examples of a commercially available product of the hybrid stabilizer include SUMILIZER GP manufactured by Sumitomo Chemical Co., Ltd.

As the heat stabilizer, the hindered phenol-based stabilizer, the semi-hindered phenol-based stabilizer, or the phosphite-based stabilizer is preferable, and the hindered phenol-based stabilizer is more preferable from the viewpoint that the heat stabilization effect is more excellent. On the other hand, from the viewpoint of electrical characteristics, a semi-hindered phenol-based stabilizer or a phosphite-based stabilizer is more preferable.

The heat stabilizers may be used alone or in combination of two or more kinds thereof. The content of the heat stabilizer is preferably 0.0001% to 10% by mass with respect to the total mass of the film. The content is more preferably 0.01% to 5% by mass, and still more preferably 0.1% to 2% by mass.

<Polyolefin>

The present film may include a polyolefin.

In the present specification, the “polyolefin” is intended to be a resin having a repeating unit based on an olefin (a polyolefin resin).

The polyolefin may be linear or branched. In addition, the polyolefin may have a cyclic structure such as a polycycloolefin.

Examples of the polyolefin include polyethylene, polypropylene (PP), polymethylpentene (TPX and the like manufactured by Mitsui Chemicals, Inc.), hydrogenated polybutadiene, a cycloolefin polymer (COP, ZEONOR manufactured by ZEON Corporation, and the like), and a cycloolefin copolymer (COC, APEL manufactured by Mitsui Chemicals, Inc., and the like).

As the polyolefin, polyethylene, COP, or COC is preferable, polyethylene is more preferable, and the low-density polyethylene (LDPE) is still more preferable.

The polyolefins may be used alone or in combination of two or more kinds thereof.

In a case where the polymer film includes a polyolefin, a content thereof is preferably 0.1% by mass or more, and more preferably 5% by mass or more with respect to the total mass of the film from the viewpoint that the surface property of the film is more excellent. The upper limit is not particularly limited, but is preferably 50% by mass or less, more preferably 40% by mass or less, and still more preferably 25% by mass or less from the viewpoint that the smoothness of the film is more excellent. In addition, in a case where the content of the polyolefin is set to 50% by mass or less, a thermal deformation temperature thereof can be easily raised sufficiently and the solder heat resistance can be improved.

<Additive>

The present film may include an additive other than the components. Examples of the additive include a plasticizer, a lubricant, inorganic and organic particles, and a UV absorbing material.

Examples of the plasticizer include an alkylphthalyl alkyl glycolate compound, a bisphenol compound (bisphenol A, bisphenol F), a phosphoric acid ester compound, a carboxylic acid ester compound, and a polyhydric alcohol. The content of the plasticizer may be 0% to 5% by mass with respect to the total mass of the film.

Examples of the lubricant include a fatty acid ester and a metal soap (for example, a stearic acid inorganic salt). The content of the lubricant may be 0% to 5% by mass with respect to the total mass of the film.

The film may contain inorganic particles and/or organic particles as a reinforcing material, a matting agent, a dielectric constant, or a dielectric loss tangent improving material. Examples of inorganic particles include silica, titanium oxide, barium sulfate, talc, zirconia, alumina, silicon nitride, silicon carbide, calcium carbonate, silicate, glass beads, graphite, tungsten carbide, carbon black, clay, mica, carbon fiber, glass fiber, and metal powder. Examples of the organic particles include crosslinked acryl and crosslinked styrene. The content of the inorganic particles and the organic particles may be 0% to 50% by mass with respect to the total mass of the film.

Examples of the UV absorbing material include a salicylate compound, a benzophenone compound, a benzotriazole compound, a substituted acrylonitrile compound, and an s-triazine compound. The content of the UV absorbing material may be 0% to 5% by mass with respect to the total mass of the film.

[Physical Properties of Polymer Film]

<Thickness>

The thickness of the film is preferably 5 to 1,000 m, more preferably 10 to 500 m, and still more preferably 20 to 300 m.

The thickness of the film is an arithmetically average value of values measured as a thickness of the polymer film at any different 100 points using a contact type thickness gauge (manufactured by Mitutoyo Corporation).

<Surface Roughness>

The surface roughness (arithmetic average roughness) Ra of the film is preferably less than 430 nm, more preferably less than 400 nm, and still more preferably less than 350 nm.

The lower limit value of the surface roughness Ra of the film is not particularly limited, and is, for example, 10 nm or more.

In a case where the surface roughness Ra of the film is within the range, it is considered that the dimensional change occurring in the film is easily absorbed, and more excellent surface properties and smoothness can be realized.

The surface roughness Ra of the film is determined by arithmetically averaging measured values obtained by a measurement using a stylus type roughness meter according to JIS B 0601 at five randomly selected positions within a region of 10 cm×10 cm in the center portion of the film.

[Method for Producing Polymer Film]

A method for producing the polymer film is not particularly limited, but the polymer film is preferably formed using a composition including at least a liquid crystal polymer and a non-liquid crystal compound, and is more preferably formed using a composition including at least a liquid crystal polymer having a reactive group at a terminal and a non-liquid crystal compound having a functional group that reacts with or interacts with the reactive group.

Examples of preferred aspects of the method for producing a polymer film include a production method including a pelletizing step of kneading each of the above-mentioned components to obtain pellets, and a film producing step of using the pellets and obtaining a polymer film. The steps will be described below.

<Pelletizing Step>

(1) Forms of Raw Material

As the liquid crystal polymer used for film production, a pellet-shaped, flake-shaped, or powdered polymer can be used as it is, but for the purpose of stabilizing the film production or uniformly dispersing additives (which means components other than the liquid crystal polymer; the same applies hereinafter), it is preferable to use pellets obtained by kneading one or more kinds of raw materials (meaning at least one of a liquid crystal polymer or an additive; the same applies hereinafter) using an extruder, followed by pelletizing.

Hereinafter, a mixture including a raw material which is a polymer, and a polymer used for producing a polymer film is also collectively referred to as a resin.

(2) Drying or Drying Alternative by Vent

Before pelletizing, it is preferable to dry the liquid crystal polymer and the additive in advance. Examples of the drying method include a method of circulating heated air having a low dew point, and a method of dehumidifying by vacuum drying. In particular, in a case of a resin which is easily oxidized, vacuum drying or drying using an inert gas is preferable.

(3) Method for Supplying Raw Materials

A method for supplying raw materials may be a method in which raw materials are mixed in advance before being kneaded and pelletized, and then supplied, a method in which raw materials are separately supplied into the extruder so as to be in a fixed ratio, or a method of a combination of the both.

(4) Atmosphere During Extrusion

In a case of melt extrusion, within a range not interfering with uniform dispersion, it is preferable to prevent thermal and oxidative deterioration as much as possible, and it is also effective to reduce an oxygen concentration by reducing the pressure using a vacuum pump or inflowing an inert gas. These methods may be carried out alone or in combination.

(5) Temperature

A kneading temperature is preferably set to be equal to or lower than a thermal decomposition temperature of the liquid crystal polymer and the additive, and is preferably set to a low temperature as much as possible within a range in which a load of the extruder and a decrease in uniform kneading property are not a problem.

(6) Pressure

A kneading resin pressure during pelletization is preferably 0.05 to 30 MPa. In a case of a resin in which coloration or gel is likely to be generated due to shearing, it is preferable to apply an internal pressure of approximately 1 to 10 MPa to the inside of the extruder to fill the inside of a twin-screw extruder with the resin raw material.

(7) Pelletizing Method

As a pelletizing method, a method of solidifying a noodle-shaped extrusion in water and then cutting the extrusion is generally used, but the pelletization may be performed by an under-water cut method for cutting while directly extruding from a mouthpiece into water after melting with the extruder, or a hot cut method for cutting while still hot.

(8) Pellet Size

A pellet size is preferably 1 to 300 mm² in a cross-sectional area and 1 to 30 mm in a length, and more preferably 2 to 100 mm² in a cross-sectional area and 1.5 to 10 mm in a length.

(Drying)

(1) Purpose of Drying

Before the molten film production, it is preferable to reduce a moisture and a volatile fraction in the pellets, and it is effective to dry the pellets. In a case where the pellets include a moisture or a volatile fraction, not only appearance is deteriorated due to incorporation of bubbles into a film to be produced or the decrease in a haze, but also physical properties may be deteriorated due to a molecular chain breakage of the liquid crystal polymer, or roll contamination may occur due to generation of monomers or oligomers. In addition, depending on the type of the liquid crystal polymer used, it may be possible to suppress generation of an oxidative crosslinked substance during the molten film production by removing dissolved oxygen by the drying.

(2) Drying Method and Heating Method

From the viewpoints of a drying efficiency and an economical efficiency, a dehumidifying hot air dryer is generally used as a drying method, but the drying method is not particularly limited as long as a desired moisture content can be obtained. In addition, there is no problem in selecting a more appropriate method according to characteristics of the physical properties of the liquid crystal polymer.

Examples of a heating method include pressurized steam, heater heating, far-infrared irradiation, microwave heating, and a heat medium circulation heating method.

<Film Producing Step>

Hereinafter, the film producing step will be described.

(1) Extrusion Conditions

Drying of Raw Materials

In a melt plasticization step for pellets using an extruder, it is preferable to reduce a moisture and a volatile fraction in the pellets as in the pelletizing step, and it is effective to dry the pellets.

Method for Supplying Raw Materials

In a case where there are multiple types of raw materials (pellets) input from the extruder supply port, the raw materials may be mixed in advance (premix method), may be separately supplied into the extruder in a fixed ratio, or may be a combination of the both. In addition, in order to stabilize the extrusion, it is generally practiced to reduce a fluctuation of the temperature and a bulk specific gravity of the raw material charged from the supply port. Moreover, from the viewpoint of a plasticization efficiency, a raw material temperature is preferably high as long as it does not block a supply port by pressure-sensitive adherence, and in a case where the raw material is in an amorphous state, the raw material temperature is preferably in the range of {Glass transition temperature (Tg) (° C.)−150° C.} to {Tg (° C.)−1° C.}, and in a case where the raw material is a crystalline resin, the raw material temperature is preferably in the range of {Melting point (Tm) (° C.)−150° C.} to {Tm (° C.)−1° C.}, and the raw material is heated or kept warm. In addition, from the viewpoint of the plasticization efficiency, the bulk specific gravity of the raw material is preferably 0.3 times or more, and more preferably 0.4 times or more in a case of a molten state. In a case where the bulk specific gravity of the raw material is less than 0.3 times the specific gravity in the molten state, it is also preferable to perform a processing treatment such as compression of the raw material into pseudo-pellets.

Atmosphere During Extrusion

As for the atmosphere during melt extrusion, it is necessary to prevent heat and oxidative deterioration as much as possible within a range that does not hinder uniform dispersion as in the pelletizing step. It is also effective to inject an inert gas (nitrogen or the like), reduce the oxygen concentration in the extruder by using a vacuum hopper, and provide a vent port in the extruder to reduce the pressure by a vacuum pump. These depressurization and injection of the inert gas may be carried out independently or in combination.

Rotation Speed

A rotation speed of the extruder is preferably 5 to 300 rpm, more preferably 10 to 200 rpm, and still more preferably 15 to 100 rpm. In a case where the rotation rate is set to the lower limit value or more, the retention time is shortened, the decrease in the molecular weight can be suppressed due to thermal deterioration, and discoloration can be suppressed. In a case where the rotation rate is set to the upper limit value or less, a breakage of a molecular chain due to shearing can be suppressed, and a decrease in the molecular weight and an increase in generation of crosslinked gel can be suppressed. It is preferable to select appropriate conditions for the rotation speed from the viewpoints of both uniform dispersibility and thermal deterioration due to extension of the retention time.

Temperature

A barrel temperature (a supply unit temperature of T₁° C., a compression unit temperature of T₂₀C, and a measuring unit temperature of T₃° C.) is generally determined by the following method. In a case where the pellets are melt-plasticized at a target temperature T° C. by the extruder, the measuring unit temperature T₃ is set to T ±20° C. in consideration of the shear calorific value. At this time, T₂ is set within a range of T₃±20° C. in consideration of extrusion stability and thermal decomposability of the resin. Generally, T₁ is set to {T₂ (° C.)−5° C.} to {T₂(° C.)-150° C.}, and the optimum value of T₁ is selected from the viewpoint of ensuring a friction between the resin and the barrel, which is a driving force (feed force) for feeding the resin, and preheating at the feed unit. In a case of a normal extruder, it is possible to subdivide each zone of T₁ to T₃ and set the temperature, and by performing settings such that the temperature change between each zone is gentle, it is possible to make it more stable. At this time, T is preferably set to be equal to or lower than the thermal deterioration temperature of the resin, and in a case where it exceeds the thermal deterioration temperature due to the shear heat generation of the extruder, it is generally performed to positively cool and remove the shear heat generation. In addition, in order to achieve both improved dispersibility and thermal deterioration, it is also effective to melt and mix a first half part in the extruder at a relatively high temperature and lower the resin temperature in a second half part.

Pressure

A resin pressure in the extruder is generally 1 to 50 MPa, and from the viewpoints of extrusion stability and melt uniformity, the resin pressure is preferably 2 to 30 MPa, and more preferably 3 to 20 MPa. In a case where the pressure in the extruder is 1 MPa or more, a filling rate of the melting in the extruder is sufficient, and therefore, the destabilization of the extrusion pressure and the generation of foreign matter due to the generation of retention portions can be suppressed. In addition, in a case where the pressure in the extruder is 50 MPa or less, it is possible to suppress the excessive shear stress received in the extruder, and therefore, thermal decomposition due to an increase in the resin temperature can be suppressed.

Retention Time

A retention time in the extruder (retention time during the film production) can be calculated from a volume of the extruder portion and a discharge capacity of the polymer, as in the pelletizing step. The retention time is preferably 10 seconds to 60 minutes, more preferably 15 seconds to 45 minutes, and still more preferably 30 seconds to 30 minutes. In a case where the retention time is 10 seconds or more, the melt plasticization and the dispersion of the additive are sufficient. In a case where the retention time is 30 minutes or less, it is preferable from the viewpoint that resin deterioration and discoloration of the resin can be suppressed.

(Filtration)

Type, Purpose of Installation, and Structure

It is generally used to provide a filtration equipment at the outlet of the extruder in order to prevent damage to the gear pump due to foreign matter included in the raw material and to extend the life of the filter having a fine pore size installed downstream of the extruder. It is preferable to perform so-called breaker plate type filtration in which a mesh-shaped filtering medium is used in combination with a reinforcing plate having a high opening ratio and having strength.

Mesh Size and Filtration Area

A mesh size is preferably 40 to 800 mesh, more preferably 60 to 700 mesh, and still more preferably 100 to 600 mesh. In a case where the mesh size is 40 mesh or more, it is possible to sufficiently suppress foreign matter from passing through the mesh. In addition, in a case where the mesh is 800 mesh or less, the improvement of the filtration pressure increase speed can be suppressed and the mesh replacement frequency can be reduced. In addition, from the viewpoints of a filtration accuracy and a strength maintenance, a plurality of types of filter meshes having different mesh sizes are often superimposed and used. Moreover, since the filtration opening area can be widened and the strength of the mesh can be maintained, the filter mesh may also be reinforced by using a breaker plate. An opening ratio of the breaker plate used is often 30% to 80% from the viewpoints of a filtration efficiency and a strength.

In addition, a screen changer with the same diameter as the barrel diameter of the extruder is often used, but in order to increase the filtration area, a larger diameter filter mesh is used by using a tapered pipe, or a plurality of breaker plates is also sometimes used by branching a flow channel. The filtration area is preferably selected with a flow rate of 0.05 to 5 g/cm² per second as a guide, more preferably 0.1 to 3 g/cm², and still more preferably 0.2 to 2 g/cm².

By capturing foreign matter, the filter is clogged and the filter pressure rises. At that time, it is necessary to stop the extruder and replace the filter, but a type in which the filter can be replaced while continuing extrusion can also be used. In addition, as a measure against an increase in the filtration pressure due to the capture of foreign matter, a measure having a function of lowering the filtration pressure by washing and removing the foreign matter trapped in the filter by reversing the flow channel of the polymer can also be used.

(Die)

Type, Structure, and Material

A molten resin from which foreign matters have been removed by filtration and in which the temperature has been made uniform by a mixer is continuously sent to the die. The die is not particularly limited as long as it is designed so that the retention of the molten resin is small, and any type of a T die, a fishtail die, or a hanger coat die, commonly used, can also be used. Among these, the hanger coat die is preferable from the viewpoints of thickness uniformity and less retention.

Multilayer Film Production

A monolayer film producing device having a low equipment cost is generally used for the production of a film. In addition, a multilayer film producing device may be used in order to provide a functional layer such as a surface protective layer, a pressure-sensitive adhesive layer, an easy adhesion layer, and/or an antistatic layer in an outer layer. Specific examples thereof include a method of performing multilayering using a multilayer feed block and a method of using a multi-manifold die. It is generally preferable to laminate the functional layer thinly on the surface layer, but the layer ratio is not particularly limited.

(Cast)

The film producing step preferably includes a step of supplying a liquid crystal polymer in a molten state from the supply unit, and a step of landing the liquid crystal polymer in the molten state on a cast roll to form a film. The molten liquid crystal polymer may be cooled and solidified, and wound as it is as the film, or it may be passed between a pair of pressing surfaces and continuously pressed to form a film.

At this time, the unit for supplying the liquid crystal polymer (melt) in a molten state is not particularly limited. For example, as a specific unit for supplying the melt, an extruder which melts the liquid crystal polymer and extrudes it into a film may be used, an extruder and a die may be used, or the liquid crystal polymer may be once solidified into a film and then molten by a heating unit to form a melt, which may be supplied to the film producing step.

In a case where the molten resin extruded from the die into a sheet is pressed by a device having a pair of pressing surfaces, the surface morphology of the pressing surface can be transferred to the film, as well as the aligning properties can be controlled by imparting elongation deformation to the composition including the liquid crystal polymer.

Film Producing Method and Type

Among the methods for forming a raw material in a molten state into a film, it is preferable to pass between two rolls (for example, a touch roll and a chill roll) from the viewpoint that a high pressing pressure can be applied and the film surface shape is excellent. Furthermore, in the present specification, in a case where a plurality of cast rolls for transporting the melt are provided, the cast roll closest to a supply unit (for example, a die) for the most upstream liquid crystal polymer is referred to as a chill roll. In addition, a method of pressing metal belts with each other or a method of combining a roll and a metal belt can also be used. In addition, in some cases, in order to improve the adhesiveness with rolls or metal belts, a film producing method such as a static electricity application method, an air knife method, an air chamber method, and a vacuum nozzle method can be used in combination on a cast drum.

In addition, in a case of obtaining a film having a multilayer structure, it is preferable to obtain the polymer film by pressing a molten polymer extruded from a die in multiple layers, but it is also possible to obtain a film having a multilayer structure by introducing a film having a monolayer structure into a pressing portion in the same manner as for molten laminating. In addition, at this time, films having different inclined structures in the thickness direction can be obtained by changing a circumferential speed difference or an alignment axis direction of the pressing portion, and films having three or more layers can be obtained by performing this step several times.

Furthermore, the touch roll may be periodically vibrated in the TD direction in a case of pressing to afford deformation.

Temperature of Molten Polymer

From the viewpoints of the improvement of the moldability of the liquid crystal polymer and the suppression of deterioration, a discharge temperature (resin temperature at an outlet of the supply unit) is preferably (Tm of liquid crystal polymer−10°) C to (Tm of liquid crystal polymer+40°) C. A guide for the melt viscosity is preferably 50 to 3,500 Pa s.

It is preferable that the cooling of the molten polymer between the air gaps is as small as possible, and it is preferable to reduce a temperature drop due to the cooling by taking measures such as increasing the film producing speed and shortening the air gap.

Temperature of Touch Roll

A temperature of the touch roll is preferably set to Tg or less of the liquid crystal polymer. In a case where the temperature of the touch roll is Tg or less of the liquid crystal polymer, pressure-sensitive adhesion of the molten polymer to the roll can be suppressed, and therefore, the film appearance is improved. For the same reason, the chill roll temperature is preferably set to Tg or less of the liquid crystal polymer.

(Film Producing Procedure for Polymer Film)

Film Producing Procedure

In the film producing step, it is preferable to perform the film production by the following procedure from the viewpoints of the film producing step for a film and the stabilization of quality.

The molten polymer discharged from the die is landed on a cast roll to form a film, which is then cooled and solidified and wound up as a film.

In a case of pressing the molten polymer, the molten polymer is passed between the first pressing surface and the second pressing surface set at a predetermined temperature, which is then cooled and solidified and wound up as a film.

<Stretching Step, Thermal Relaxation Treatment, and Thermal Fixation Treatment>

Furthermore, after producing a non-stretched film by the method, the non-stretched film may be continuously or discontinuously stretched and/or subjected to a thermal relaxation treatment or a thermal fixation treatment. For example, each step can be carried out by the combination of the following (a) to (g). In addition, the order of the machine-direction stretching and the cross-direction stretching may be reversed, each step of the machine-direction stretching and the cross-direction stretching may be performed in multiple stages, and each step of the machine-direction stretching and the cross-direction stretching may be combined with oblique-direction stretching or simultaneous biaxial stretching.
(a) Cross-direction stretching
(b) Cross-direction stretching→Thermal relaxation treatment
(c) Machine-direction stretching
(d) Machine-direction stretching→Thermal relaxation treatment
(e) Machine-direction (cross-direction) stretching→Cross-direction (machine-direction) stretching
(f) Machine-direction (cross-direction) stretching→Cross-direction (machine-direction) stretching→Thermal relaxation treatment
(g) Cross-direction stretching→Thermal relaxation treatment→Machine-direction stretching→Thermal relaxation treatment

Machine-Direction Stretching

The machine-direction stretching can be achieved by making the circumferential speed on the outlet side faster than the circumferential speed on the inlet side while heating between the two pairs of rolls. From the viewpoint of a curl of a film, it is preferable that the film temperatures are the same on the front and back surfaces, but in a case where optical characteristics are controlled in the thickness direction, the stretching can be performed at different temperatures on the front and back surfaces. Furthermore, the stretching temperature herein is defined as a temperature on the lower side of the film surface. The machine-direction stretching step may be carried out in either one step or multiple steps. The preheating of the film is generally performed by passing it through a temperature-controlled heating roll, but in some cases, a heater can be used to heat the film. In addition, a ceramic roll or the like having improved adhesiveness can also be used in order to prevent the film from pressure-sensitive adhesiveness to the roll.

Cross-Direction Stretching

As the cross-direction stretching step, normal cross-direction stretching can be adopted. That is, examples of the normal cross-direction stretching include a stretching method in which both ends in the width direction of the film are gripped with clips, and the clips are widened while being heated in an oven using a tenter. With regard to the cross-direction stretching step, for example, methods described in JP1987-035817U (JP-S62-035817U), JP2001-138394A, JP1998-249934A (JP-H10-249934A), JP1994-270246A (JP-H06-270246A), JP1992-030922U (JP-H04-030922U), and JP1987-152721A (JP-S62-152721A) can be used, and these methods are herein incorporated by reference.

A stretching ratio (cross-direction stretching ratio) in the width direction of the film in the cross-direction stretching step is preferably 1.2 to 6 times, more preferably 1.5 to 5 times, and still more preferably 2 to 4 times. In addition, the cross-direction stretching ratio is preferably larger than the stretching ratio of the machine-direction stretching in a case where the machine-direction stretching is performed.

A stretching temperature in the cross-direction stretching step can be controlled by blowing air at a desired temperature into a tenter. The film temperatures may be the same or different on the front and back surfaces for the same reason as in the machine-direction stretching. The stretching temperature used herein is defined as a temperature on the lower side of the film surface. The cross-direction stretching step may be carried out in one step or in multiple steps. In addition, in a case of performing cross-direction stretching in multiple stages, the cross-direction stretching may be performed continuously or intermittently by providing a zone in which widening is not performed. For such the cross-direction stretching, in addition to the normal cross-direction stretching in which a clip is widened in the width direction in a tenter, a stretching method as below, in which a clip is widened by gripping, can also be applied.

Oblique-Direction Stretching

In the oblique-direction stretching step, the clips are widened in the cross-direction in the same manner as in the normal cross-direction stretching, but can be stretched in an oblique direction by switching the transportation speeds of the left and right clips. As the oblique-direction stretching step, for example, the methods described in JP2002-022944A, JP2002-086554A, JP2004-325561A, JP2008-023775A, and JP2008-110573A can be used.

Simultaneous Biaxial Stretching

In the simultaneous biaxial stretching, clips are widened in the cross-direction, and simultaneously stretched or contracted in the machine direction, in a similar manner to the normal cross-direction stretching. As the simultaneous biaxial stretching, for example, the methods described in JP1980-093520U (JP-S55-093520U), JP1988-247021A (JP-S63-247021A), JP1994-210726A (JP-H06-210726A), JP1994-278204A (JP-H06-278204A), JP2000-334832A, JP2004-106434A, JP2004-195712A, JP2006-142595A, JP2007-210306A, JP2005-022087A, and JP2006-517608A can be used.

Heat Treatment to Improve Bowing (Axis Misalignment) Since the end part of the film is gripped by the clip in the cross-direction stretching step, the deformation of the film due to a thermal contraction stress generated during a heat treatment is large at the center of the film and is small at the end parts, and as a result, the characteristics in the width direction can be distributed. In a case where a straight line is drawn along the cross-direction on a surface of the film before the heat treatment step, the straight line on the surface of the film after the heat treatment step is an arcuate shape in which the center portion is recessed toward the downstream side. This phenomenon is called a bowing phenomenon, and is a cause that disturbs isotropy and widthwise uniformity of the film.

With an improvement method therefor, it is possible to reduce a variation in an alignment angle due to the bowing by performing preheating before the cross-direction stretching or by performing the thermal fixation after the stretching. The preheating and the thermal fixation may be performed, but it is preferable to perform the both. It is preferable to perform the preheating and the thermal fixation by gripping with a clip, that is, it is preferable to perform the preheating and the thermal fixation continuously with the stretching.

The preheating is performed at a temperature higher than the stretching temperature by preferably about 1° C. to 50° C., more preferably 2° C. to 40° C., and still more preferably 3° C. to 30° C. The preheating time is preferably 1 second to 10 minutes, more preferably 5 seconds to 4 minutes, and still more preferably 10 seconds to 2 minutes.

During the preheating, it is preferable to keep the width of the tenter almost constant. The term “almost” as mentioned herein refers to +10% of the width of the non-stretched film.

The thermal fixation is performed at a temperature lower than the stretching temperature by preferably about 1° C. to 50° C., more preferably 2° C. to 40° C., and still more preferably 3° C. to 30° C. In particular, it is preferable that the thermal fixation temperature is no higher than the stretching temperature and no higher than the Tg of the liquid crystal polymer.

The thermal fixation time is preferably 1 second to 10 minutes, more preferably 5 seconds to 4 minutes, and still more preferably 10 seconds to 2 minutes. During thermal fixation, it is preferable to keep the width of the tenter almost constant. The term “almost” as mentioned herein means 0% (the same width as the tenter width after stretching) to −30% (30% smaller than the tenter width after stretching=reduced width) of the tenter width after the completion of stretching. Examples of other known methods include the methods described in JP1989-165423A (JP-HO1-165423A), JP1991-216326A (JP-H03-216326A), JP2002-018948A, and JP2002-137286A.

Thermal Relaxation Treatment

After the stretching step, a thermal relaxation treatment in which the film is heated to contract the film may be performed. By performing the thermal relaxation treatment, the thermal contraction rate at the time of using the film can be reduced. It is preferable that the thermal relaxation treatment is carried out at at least one timing of a time after film production, a time after machine-direction stretching, or a time after cross-direction stretching.

The thermal relaxation treatment may be continuously performed online after the stretching, or may be performed offline after winding after the stretching. Examples of the temperature of the thermal relaxation treatment include a temperature from a glass transition temperature Tg to a melting point Tm of the liquid crystal polymer. In a case where there is a concern about oxidative deterioration of the film, the thermal relaxation treatment may be performed in an inert gas such as a nitrogen gas, an argon gas, and a helium gas.

<Post-Heating Treatment>

From the viewpoint that the film according to the embodiment of the present invention can be easily produced, it is preferable that an unstretched film formed by the method or a film subjected to machine-direction stretching may be subjected to cross-direction stretching and then subjected to a post-heating treatment while fixing the film width.

A detailed mechanism that makes it possible to easily obtain any of a film in which a relaxation peak disappearance temperature in the frequency dependence of the dielectric loss tangent is within the range by performing the post-heating treatment after performing the cross-direction stretching, and a film in which the A value is in the range is not clarified, but is presumed to be as follows by the present inventors. That is, in the process for the post-heating treatment, a reaction from the reactive group at a molecular terminal of the liquid crystal polymer in the film to the functional group of the non-liquid crystal compound proceeds, or an interaction between the reactive group and the functional group is reinforced. With this, it is presumed that the motility of the liquid crystal polymer molecule is constrained, and as a result, the relaxation peak disappearance temperature in the frequency dependence of the dielectric loss tangent increases while the A value measured by the measurement 1 decreases.

In the post-heating treatment, a heat treatment is performed while fixing the film so as not to cause contraction of the film in the width direction by a fixing method such as gripping of both ends of the film in the width direction with a jig (clip). The film width after the post-heating treatment is preferably 85% to 105%, and more preferably 95% to 102% with respect to the film width before the post-heating treatment.

The heating temperature in the post-heating treatment is preferably {Tm−200}° C. or higher, more preferably {Tm−100}° C. or higher, and still more preferably {Tm−50}° C. or higher, with the melting point of the liquid crystal polymer being taken as the Tm (° C.). Alternatively, the heating temperature in the post-heating treatment is preferably 240° C. or higher, more preferably 255° C. or higher, and still more preferably 270° C. or higher. The upper limit of the heating temperature in the post-heating treatment is preferably {Tm+70}° C. or lower, more preferably {Tm+50}° C. or lower, and still more preferably {Tm+30}° C. or lower.

Examples of a heating unit used for the post-heating treatment include a hot air dryer, an infrared heater, a pressurized steam, microwave heating, and a heat medium circulation heating method. Among those, the hot air dryer is preferable from the viewpoint of a productivity. A treatment time of the post-heating treatment can be appropriately adjusted according to the type of the liquid crystal polymer, the heating unit, and the heating temperature. In a case where the hot air dryer is used, the treatment time is preferably 1 second to 20 hours, and more preferably 1 second to 1 hour.

<Surface Treatment>

Since the adhesiveness between the film and a metal layer such as a copper foil and a copper plating layer can be further improved, it is preferable to subject the film to a surface treatment. Examples of the surface treatment include a glow discharge treatment, an ultraviolet irradiation treatment, a corona treatment, a flame treatment, and an acid or alkali treatment. The glow discharge treatment as mentioned herein may be a treatment with a low-temperature plasma generated in a gas at a low pressure ranging from 10⁻³ to 20 Torr, and is preferably a plasma treatment under atmospheric pressure.

The glow discharge treatment is performed using a plasma-excited gas. The plasma-excited gas refers to a gas that is plasma-excited under the above-described conditions, and examples thereof include argon, helium, neon, krypton, xenon, nitrogen, and carbon dioxide, fluorocarbons such as tetrafluoromethane, and mixtures of these.

It is also preferable to provide the film with an undercoat layer for adhesiveness to the metal layer. This layer may be applied after the surface treatment or may be applied without the surface treatment.

The surface treatment and the undercoating step can be incorporated at the end of the film producing step, can be carried out alone, or can be carried out in a copper foil or a copper plating layer applying step.

It is also useful to subject the film to an aging treatment at a temperature which is temperature equal to or lower than the Tg of the liquid crystal polymer in order to improve the mechanical properties, the thermal dimensional stability, or the winding shape of the wound film.

In addition, with regard to the film, the smoothness of the film may be further improved by further performing a step of compressing the film with a heating roll and/or a step of stretching the film after performing the film producing step.

In the manufacturing method above, the case where the film is a monolayer is described, but the film may have a laminated structure in which a plurality of layers are laminated.

The polymer film is preferably used for the production of a laminate which will be described later by laminating the polymer film with a metal layer. In addition, the polymer film can also be used as a substrate film.

[Laminate]

The laminate of an embodiment of the present invention has the polymer film and a metal layer arranged on at least one surface of the polymer film.

In the laminate, one metal layer may be arranged on one surface of the polymer film, or two metal layers may be arranged on both surfaces of the polymer film.

As the material forming the metal layer, a metal used for electrical connection is preferable. Examples of such metals include copper, gold, silver, nickel, aluminum, and alloys including any of these metals. Examples of the alloy include a copper-zinc alloy, a copper-nickel alloy, and a zinc-nickel alloy.

As the metal layer, a copper layer is preferable from the viewpoint that the conductivity and the workability are excellent. The copper layer is a layer consisting of copper or a copper alloy including 95% by mass or more of copper. Examples of the copper layer include a rolled copper foil produced by a rolling method, and an electrolytic copper foil produced by an electrolysis method. The metal layer may be subjected to a chemical treatment such as acid cleaning.

The thickness of the metal layer is not particularly limited, and is appropriately selected depending on a use of a circuit board, but the thickness is preferably 4 to 100 μm, and more preferably 10 to 35 m from the viewpoints of a wiring line conductivity and an economical efficiency.

A maximum height Rz on a surface of the metal layer constituting the laminate, on the side facing the polymer film, is preferably 5 m or less, more preferably 4 m or less, and still more preferably 3 m or less from the viewpoint that a transmission loss of the laminate in a case of being used as a communication circuit board can be reduced. The lower limit is not particularly limited, but is preferably 0.1 m or more.

The maximum height Rz on a surface of the metal layer is determined by measuring a maximum height Rz at any 10 points and arithmetically averaging the values obtained from the measurement, using a stylus type roughness meter according to JIS B0601, on a surface of the metal layer peeled from the laminate, on the side facing the polymer film.

In a case where a commercially available metal foil is used as the metal layer, a numerical value of the maximum height Rz described as a catalog value of the commercially available product may be used.

A peel strength between the polymer film and the metal layer in the laminate is preferably more than 0.5 kN/m, more preferably 0.55 kN/m or more, still more preferably 0.6 kN/m or more, and particularly preferably 0.65 kN/m or more. The more the peel strength, the more excellent the adhesiveness between the polymer film and the metal layer.

The upper limit value of the peel strength of the laminate is not particularly limited, and may be 1.0 or more.

A method for measuring the peel strength of the laminate will be described in the section of Examples which will be described later.

The laminate may have a layer other than the polymer film and the metal layer, as necessary. Examples of such an other layer include an adhesive layer which will be described later, a rust preventive layer, and a heat resistant layer.

A method for producing the laminate is not particularly limited, and a laminate having a polymer film, and for example, a polymer film and a metal foil consisting of the metal can be laminated, and then compression-bonded under high temperature conditions to produce a laminate having the polymer film and a metal layer. Furthermore, in a case where a metal foil having a maximum surface height Rz within the preferred range is used, the polymer film and the metal foil are bonded to each other so that a surface of the metal foil is in contact with the polymer film.

The method and the conditions for the compression-bonding treatment are not particularly limited, and are appropriately selected from known methods and conditions. The temperature condition for the compression-bonding treatment is preferably 90° C. to 310° C., and the pressure condition for the compression-bonding treatment is preferably 1 to 100 MPa.

In the laminate, the polymer film and the metal layer may be laminated via the adhesive layer in order to improve the adhesiveness. That is, the laminate may have an adhesive layer between the polymer film and the metal layer.

The adhesive layer is not particularly limited as long as it is a known adhesive layer used for manufacturing a wiring board such as a copper-clad laminate, and examples thereof include a cured product of an adhesive composition including a known curable resin such as a polyimide and an epoxy resin.

The laminate having an adhesive layer can be produced by, for example, applying an adhesive composition to at least one surface of a polymer film or at least one surface of a metal foil, subjecting the coating film to drying and/or curing as necessary to form an adhesive layer, and then laminating the polymer film and the metal foil via the adhesive layer according to the method.

Examples of the use of the laminate include a laminated circuit board, a flexible laminated board, and a wiring substrate such as a flexible printed circuit (FPC). The laminate is particularly preferably used as a high-speed communication substrate.

### EXAMPLES

Hereinafter, Examples and Comparative Examples of the present invention will be described.

The liquid crystal polymer films of Examples 1 to 7 and Comparative Examples 1 and 2 were manufactured by production methods shown below, and evaluations which will be described later were performed. First, a method for producing a liquid crystal polymer film of each of Examples and Comparative Examples will be described.

[Raw Materials]

(Liquid Crystal Polymer)
LCP1: A polymer synthesized based on Example 1 of JP2019-116586A (melting point Tm: 320° C., dielectric loss tangent: 0.0007).
LCP2: LAPEROS C-950 manufactured by Polyplastics Co., Ltd. (melting point Tm: 290° C., dielectric loss tangent: 0.0017)
LCP1 is composed of a repeating unit derived from 6-hydroxy-2-naphthoic acid, a repeating unit derived from 4,4′-dihydroxybiphenyl, a repeating unit derived from terephthalic acid, and a repeating unit derived from 2,6-naphthalenedicarboxylic acid.
LCP2 is a polymer represented by the following chemical formula.

In addition, the dielectric loss tangent of each liquid crystal polymer was measured by a cavity resonator perturbation method using a cavity resonator (CP-531 manufactured by Kanto Electronics Application & Development, Inc.) according to the above-mentioned method.

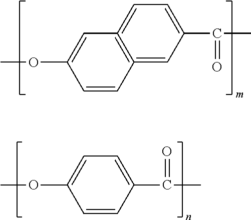

(Non-Liquid Crystal Compound)
Compound 1: BONDFIRST (registered trademark) E manufactured by Sumitomo Chemical Co., Ltd. (copolymer of ethylene and glycidyl methacrylate (E-GMA copolymer))
Compound 2: ADMER (registered trademark) manufactured by Mitsui Chemicals, Inc. (copolymer of ethylene and maleic acid anhydride (E-MAH copolymer))
Compound 3: TUFTEC manufactured by Asahi Kasei Corporation (amine-modified hydrogenated styrene-butadiene copolymer (SEBS-NH₂ copolymer))
Compound 4: HIMILAN manufactured by Mitsui-Dow Polychemical Co., Ltd. (ionomer in which a molecule of an ethylene-methacrylic acid copolymer is crosslinked with a metal ion)

Each of the compounds 1 to 3 has a covalent-bonding group and a hydrogen-binding group, and the compound 4 has an ion-bonding group.

(Heat Stabilizer)
Heat Stabilizer 1: Irganox 1010 (hindered phenol-based heat stabilizer) manufactured by BASF

### Example 1

<Manufacture of Film>

—Supply Step—

A liquid crystal polymer LCP1 (100 parts by mass), the compound 1 (1.7 parts by mass), and the heat stabilizer 1 (0.5 parts by mass) were mixed, kneaded using an extruder, and pelletized. The pelletized resin composition was dried for 12 hours using a dehumidifying hot air dryer having a heating temperature of 80° C. and a dew point temperature of −45° C. As a result, a moisture content of the pellets of the resin composition was set to 50 ppm or less.

Furthermore, the content of the functional groups (functional group concentration) contained in the compound 1 with respect to the total mass of the film was 0.1% by mass.

—Film Producing Step—

The dried pellets were supplied into a cylinder from the same supply port of a twin-screw extruder having a screw diameter of 50 mm, heated, and kneaded at 270° C. to 350° C., and a melted film-like liquid crystal polymer was discharged from a die having a die width of 750 mm and a slit spacing of 300 m. The uneven thickness of the discharged film-like liquid crystal polymer in the width direction was improved by finely adjusting a clearance of the die lip portion. In this manner, a film having a thickness of 50 m was manufactured.

—Post-Heating Treatment—

The obtained film was subjected to the following post-heating treatment using a hot air dryer.

Both the ends of the film in the width direction were gripped with a jig and the film was fixed so as not to shrink in the width direction. The film fixed with a jig was placed in the hot air dryer and heated for 1 hour under a condition of a film surface temperature of 320° C., and then the film was taken out from the hot air dryer.

In the post-heating treatment, a film for measuring the film surface temperature was installed in the vicinity of the film to be subjected to a heating treatment, and a film surface temperature of the film was measured using a thermocouple attached to a surface of the film for measuring a film surface temperature with a tape made of a polyimide material.

—Surface Treatment—

One surface of the film which had been subjected to a post-heating treatment was subjected to an atmospheric pressure plasma treatment (11 kV, 16 mm/s, 1 round, He or N₂ plasma) to manufacture a polymer film (film 1).

<Manufacture of Laminate>

—Formation of Adhesive Layer—

17.7 g of a polyimide resin solution (“PIAD-200” manufactured by Arakawa Chemical Industries, Ltd.), 0.27 g of N,N-diglycidyl-4-glycidyloxyaniline, and 1.97 g of toluene were mixed and stirred to obtain an adhesive varnish having a concentration of solid contents of 28% by mass.

The obtained adhesive varnish was applied onto the surface of the film 1, which had been subjected to a surface treatment, using an applicator. The coating film was dried under the conditions of 85° C. for 1 hour to provide an adhesive layer having a film thickness of 0.8 m, and a film 1 with an adhesive layer was manufactured.

—Formation of Laminate with Copper Layer—

The obtained film 1 with an adhesive layer and a non-roughening-treated copper foil (“CF-T9DA-SV-18” manufactured by Fukuda Metal Foil & Powder Co., Ltd., a thickness of 18 m) were laminated so that the adhesive layer of the film 1 with an adhesive layer and the non-roughening-treated surface (maximum height Rz of 0.85 m) of the non-roughening-treated copper foil were in contact with each other, and then compression-bonded for 1 hour under the conditions of 200° C. and 4 MPa using a hot press machine (Toyo Seiki Seisaku-sho, Ltd.) to obtain a laminate 1 in which the film 1, the adhesive layer, and the copper foil were laminated in this order.

### Examples 2 to 7

Polymer films and laminates of Examples 2 and 3 were each manufactured according to the same method as described in Example 1, except that the formulation of the resin composition was adjusted so that the functional group concentrations were 0.2% by mass and 0.3% by mass, respectively, in the supply step.

A polymer film and a laminate of Example 4 were manufactured according to the same method as described in Example 3, except that the liquid crystal polymer LCP2 was used instead of the liquid crystal polymer LCP1 in the supply step.

Polymer films and laminates of Examples 5, 6 and 7 were each manufactured according to the same method as described in Example 3, except that compounds 2, 3 and 4 were used instead of the compound 1 in the supply step.

### Comparative Examples 1 and 2

A polymer film and a laminate of Comparative Example 1 were manufactured according to the same method as described in Example 1, except that the compound 1 which was a non-liquid crystal compound was not used in the supply step.

In addition, a polymer film and a laminate of Comparative Example 2 were manufactured according to the same method as described in Example 1, except that the post-heating treatment was not performed in the manufacture of the film.

[Evaluation Tests]

The following evaluation tests were performed on the film and the laminate produced by the production method of each of the above-described examples.

—Dielectric Loss Tangent—

A center part of each film was sampled, and the dielectric loss tangent in a frequency band of 28 GHz was measured in an environment at a temperature of 23° C. and a humidity of 50% RH, using a split cylinder type resonator (“CR-728” manufactured by Kanto Electronics Application & Development, Inc.) and a network analyzer (Keysight N5230A).

—Relaxation Peak Disappearance Temperature—

For a sample obtained from the center portion of each film, the relaxation peak disappearance temperature was determined by the above-described method. The measurement of the frequency dependence of the dielectric loss tangent was performed using a dielectric loss tangent measuring device “Alpha-A Analyzer” manufactured by Novocontrol Technologies GmbH & Co. KG. In addition, the measurement of the frequency dependence of the dielectric loss tangent was performed in a frequency range of 1 to 10⁷ Hz, and the measurement of the frequency dependence of the dielectric loss tangent was performed in a range of −90 to 60° C. by changing the temperature condition every 10° C.

—A Value—

Each film was dissolved in pentafluorophenol to obtain a 0.1% by mass solution, and then 2 parts by mass of pentafluorophenol in chloroform was added thereto to prepare a sample for measuring the A value. With regard to the obtained sample, a number-average molecular weight in terms of standard polystyrene was measured using GPC (“HLC-8320GPC” manufactured by Tosoh Corporation), and an A value (eq/t) was calculated based on Expression (A1) from the obtained number-average molecular weight.

—Peeling Strength Test—

Each laminate was cut into a strip in 1 cm×5 cm to manufacture a sample. A peel strength (unit: kN/m) of the obtained sample was measured according to the method for measuring a peel strength under normal conditions described in JIS C 6481. The peeling of the copper foil from the sample in a peel strength test was performed at an angle of 90° with respect to the sample and a peeling rate of 50 mm/sec.

The measurement results of the peel strength of each laminate are shown in the following table.

[Results]

The formulations of the raw materials used in the production of each film and the evaluation results of each film or each laminate are shown in Table 1.

TABLE 1

| | | | | | Evaluation results | | | |
|---|---|---|---|---|---|---|---|---|
| | Formulation of raw materials | | | | Polymer film | | | |
| | Liquid crystal | | Non-liquid crystal polymer | | | Relaxation peak | | |
| | polymer | | | Functional group | | disappearance | | Laminate |
| | | Tm | | concentration | Dielectric | temperature | A value | Peel strength |
| | Type | [° C.] | Type | [%] | loss tangent | [° C.] | [eq/t] | [KN/m] |
| Example 1 | LCP1 | 320 | Compound 1 | 0.1 | 0.001 | −60 | 20 | 0.55 |
| Example 2 | LCP1 | 320 | Compound 1 | 0.2 | 0.001 | −40 | 17 | 0.60 |
| Example 3 | LCP1 | 320 | Compound 1 | 0.3 | 0.001 | −20 | 14 | 0.75 |
| Example 4 | LCP2 | 290 | Compound 1 | 0.3 | 0.003 | −20 | 15 | 0.70 |
| Example 5 | LCP1 | 320 | Compound 2 | 0.3 | 0.001 | −75 | 43 | 0.55 |
| Example 6 | LCP1 | 320 | Compound 3 | 0.3 | 0.001 | −75 | 46 | 0.55 |
| Example 7 | LCP1 | 320 | Compound 4 | 0.3 | 0.001 | −80 | 52 | 0.55 |
| Comparative | LCP1 | 320 | None | — | 0.001 | −85 | 61 | 0.50 |
| Example 1 | | | | | | | | |
| Comparative | LCP1 | 320 | Compound 1 | 0.1 | 0.001 | −85 | 63 | 0.50 |
| Example 2 | | | | | | | | |

From the results shown in the tables, it was confirmed that the objects of the present invention can be accomplished with the polymer film of the embodiment of the present invention.

It was confirmed that in a case where the relaxation peak disappearance temperature is −50° C. or higher, the adhesiveness between the polymer film and the copper foil is more excellent, and in a case where the relaxation peak disappearance temperature is −30° C. or higher, the adhesiveness between the polymer film and the copper foil is still more excellent (comparison of Examples 1 to 7).

In addition, it was confirmed that in a case where the A value is 18 eq/t or less, the adhesiveness between the polymer film and the copper foil is more excellent, and in a case where the A value is 15 eq/t or less, the adhesiveness between the polymer film and the copper foil is still more excellent (comparison of Examples 1 to 7)

What is claimed is:

1. A polymer film having a dielectric loss tangent under conditions of a temperature of 23° C. and a frequency of 28 GHz of 0.005 or less,
wherein a maximum value of a temperature at which a relaxation peak is not measured on a frequency-dependent curve of the dielectric loss tangent of the polymer film, obtained by measurement in a frequency range of 1 to 10⁷ Hz, is −80° C. or higher.

2. A polymer film having a dielectric loss tangent under conditions of a temperature of 23° C. and a frequency of 28 GHz of 0.005 or less,
wherein an A value obtained by a measurement method 1 which will be described later is 1 to 60 eq/t,
Measurement method 1: an A value is calculated according to the following Expression (A1) from a number-average molecular weight in terms of standard polystyrene obtained by gel permeation chromatography for a polymer solution obtained by dissolving a polymer film in a solvent,
A value=(10⁶/number-average molecular weight)×2. Expression (A1)

3. The polymer film according to claim 1,
wherein the polymer film includes a compound having a structure of a liquid crystal polymer and a structure of a non-liquid crystal compound.

4. The polymer film according to claim 1,
wherein the polymer film is formed of a composition including a liquid crystal polymer having a reactive group at a terminal and a non-liquid crystal compound having a functional group that reacts with or interacts with the reactive group.

5. The polymer film according to claim 4,
wherein the functional group is a group capable of forming a covalent bond by reacting with the reactive group.

6. The polymer film according to claim 5,
wherein the group capable of forming a covalent bond is at least one functional group selected from the group consisting of an epoxy group, an amino group, an oxetanyl group, an isocyanate group, an acid anhydride group, a carbodiimide group, an N-hydroxyester group, a glyoxal group, an imidoester group, an alkyl halide group, a thiol group, a hydroxyphenyl group, and a carboxy group.

7. The polymer film according to claim 4,
wherein the functional group is a group capable of forming an ion bond with the reactive group, a group capable of forming a hydrogen bond with the reactive group, or a group having a dipole-dipole interaction with the reactive group.

8. The polymer film according to claim 3,
wherein a content of the non-liquid crystal compound is 0.1% to 50% by mass with respect to a total mass of the polymer film.

9. The polymer film according to claim 3,
wherein the non-liquid crystal compound is a polymer compound.

10. The polymer film according to claim 3,
wherein the liquid crystal polymer has a melting point of 250° C. or higher.

11. The polymer film according to claim 3,
wherein the liquid crystal polymer has a melting point of 380° C. or lower.

12. The polymer film according to claim 3,
wherein the liquid crystal polymer has at least one selected from the group consisting of repeating units represented by Formulae (1) to (3),
—O—Ar1-CO— (1)
—CO—Ar2-CO— (2)
—X—Ar3-Y— (3)
in Formula (1), Ar1 represents a phenylene group, a naphthylene group, or a biphenylylene group,
in Formula (2), Ar2 represents a phenylene group, a naphthylene group, a biphenylylene group, or a group represented by Formula (4),
in Formula (3), Ar3 represents a phenylene group, a naphthylene group, a biphenylylene group, or the group represented by Formula (4), and X and Y each independently represent an oxygen atom or an imino group,
—Ar4-Z—Ar5- (4)
in Formula (4), Ar4 and Ar5 each independently represent a phenylene group or a naphthylene group, and Z represents an oxygen atom, a sulfur atom, a carbonyl group, a sulfonyl group, or an alkylene group, and
the phenylene group, the naphthylene group, and the biphenylylene group may have a substituent selected from the group consisting of a halogen atom, an alkyl group, and an aryl group.

13. The polymer film according to claim 3,
wherein the liquid crystal polymer has at least one selected from the group consisting of a repeating unit derived from parahydroxybenzoic acid and a repeating unit derived from 6-hydroxy-2-naphthoic acid.

14. The polymer film according to claim 3,
wherein the liquid crystal polymer has at least one selected from the group consisting of a repeating unit of 6-hydroxy-2-naphthoic acid, a repeating unit of an aromatic diol compound, a repeating unit of terephthalic acid, and a repeating unit of 2,6-naphthalenedicarboxylic acid.

15. A laminate comprising:
the polymer film according to claim 1; and
a metal layer arranged on at least one surface of the polymer film.

16. The laminate according to claim 15,
wherein two of the metal layers are arranged on both surfaces of the polymer film.

17. The laminate according to claim 15,
wherein the metal layer is a copper layer.

18. The laminate according to claim 15,
wherein a maximum height Rz of a surface of the metal layer on a side facing the polymer film is 5 m or less.

19. The laminate according to claim 15,
wherein a peel strength between the polymer film and the metal layer is more than 0.5 kN/m.

20. The polymer film according to claim 2,
wherein the polymer film includes a compound having a structure of a liquid crystal polymer and a structure of a non-liquid crystal compound.
